(19) United States
(12) Patent Application Publication
(10) Pub. No.: US 2004/0206993 A1
(43) Pub. Date: Oct. 21, 2004

(54) Process for fabrication of ferroelectric devices with reduced hydrogen ion damage

(75) Inventors: Karl Hornik, Kanagawa-ken (JP); Haoren Zhuang, Tokyo-to (JP); Bum Ki Moon, Tokyo-to (JP); Andreas Hilliger, Kanagawa-ken (JP); Katsuaki Natori, Kanagawa-ken (JP)

Correspondence Address: LERNER, DAVID, LITTENBERG,, KRUMHOLZ & MENTLIK, 600 SOUTH AVENUE WEST, WESTFIELD, NJ, 07090, US

(73) Assignees: Infineon Technologies AG, Munich (DE); Kabushiki Kaisha Toshiba, Tokyo (JP)

(21) Appl. No.: 10/417,503

(22) Filed: Apr. 17, 2003

(51) Int. Cl. H01L 21/00; H01L 29/76; H01L 31/062

(52) U.S. Cl. 257/295; 438/3; 257/306; 438/244; 257/310

(57) ABSTRACT

A ferrocapacitor device comprising a ferroelectric capacitor structure which includes a bottom electrode 5, a ferroelectric layer 7, and a top electrode 9, formed over a substructure 1. A first Al₂O₃ cover layer 15 is deposited over the structure by a physical vapour deposition process (such as sputtering), and a second Al₂O₃ cover layer 17 is deposited over the first Al₂O₃ cover layer 15 by atomic layer deposition. The first Al₂O₃ cover layer 15 protects the capacitor structure during the formation of the second Al₂O₃ cover layer 17, and the second Al₂O₃ cover layer 17 protects the capacitor structure during back end processes performed on the FeRAM device.

### FIELD OF THE INVENTION

The present invention relates to fabrication processes for ferroelectric devices (in particular FeRAM devices) which include one or more ferrocapacitors, and to ferroelectric devices produced by the fabrication processes.

### BACKGROUND OF INVENTION

It is known to produce ferroelectric devices such as FeRAM devices which include ferroelectric capacitors produced by depositing the following layers onto a substructure: a bottom (metal) electrode layer, a ferroelectric layer such as lead zirconium titanate (PZT) or strontium bismuth tantalate (SBT), and a top (metal) electrode layer. Hardmask elements, typically formed Tetraethyl Orthosilicate (TEOS), are deposited over the top electrode layer, and used to etch the structure so as to remove portions of the bottom electrode layer, ferroelectric layer, and top electrode layer which are not under the hardmask elements. The etching separates the top electrode layer into top electrodes, the bottom electrode layer into bottom electrodes, and the ferroelectric layer into ferroelectric elements sandwiched by respective pairs of top electrodes and bottom electrodes.

There remain several integration challenges for realising commercial FeRAM devices, such as damage caused during existing fabrication processes to the ferroelectric layer. These problems are mostly due to hydrogen generated during the back-end process of forming intermetal dielectric (IMD) and passivation layers. Hydrogen ions and electrons are generated in these processes, e.g. during plasma-enhanced chemical vapour deposition (PECVD) processes using SiH₄-based chemistry, and diffuse into the ferroelectric layers, where they pin the ferroelectric domains. Moreover, in the worst case they will cause the ferroelectric material, and indeed certain electrode materials such as SrRuO₃ (Strontium Ruthenium Oxide, also sometimes referred to as “SRO”) to decompose. Both of these effects lead to considerable degradation of the ferroelectric performance of the capacitor.

A few efforts have previously been reported to solve the problem of hydrogen-induced damage, such as the insertion of several Al₂O₃ layers (referred to as encapsulation layers or cover layers) over the capacitor. However, these approaches have limited success, since conventional Al₂O₃ deposition methods (generally sputtering) produce films which achieve insufficient prevention of H₂-diffusion.

For this reason it has alternatively been proposed that atomic layer deposition (ALD) should be used to produce a high-quality Al₂O₃ barrier film. However, this too is not really satisfactory, because the ALD process itself employs aggressive chemistry (radicals and high temperatures) compared with sputtering technology, and this chemistry itself produces substantial degradation of the capacitor.

### SUMMARY OF THE INVENTION

The present invention aims to provide a new and useful method for fabrication of a ferroelectric device, and in particular one which addresses the above problem. The invention further aims to provide a ferroelectric device produced by the method.

In general terms, the present invention proposes that a first Al₂O₃ layer should be deposited over the capacitor by physical vapour deposition, and that a second Al₂O₃ layer should be deposited over the first Al₂O₃ layer by ALD. The second Al₂O₃ layer is highly effective in preventing the damage to the capacitor due to diffusion of hydrogen ions and/or electrons, while the first Al₂O₃ layer very much reduces the damage caused to the capacitor by the ALD process,

Preferably the physical vapour deposition technique used to deposit the first Al₂O₃ layer is sputtering.

Preferably the second Al₂O₃ layer is deposited directly over the first Al₂O₃ layer (i.e. without an intermediate layer in between).

In a second aspect, the invention proposes a ferroelectric device produced by the method.

### BRIEF DESCRIPTION OF THE FIGURES

Preferred features of the invention will now be described, for the sake of illustration only, with reference to the following figures in which:

FIG. 1 shows the structure of a ferroelectric device which is an embodiment of the invention.

### DETAILED DESCRIPTION OF THE EMBODIMENTS

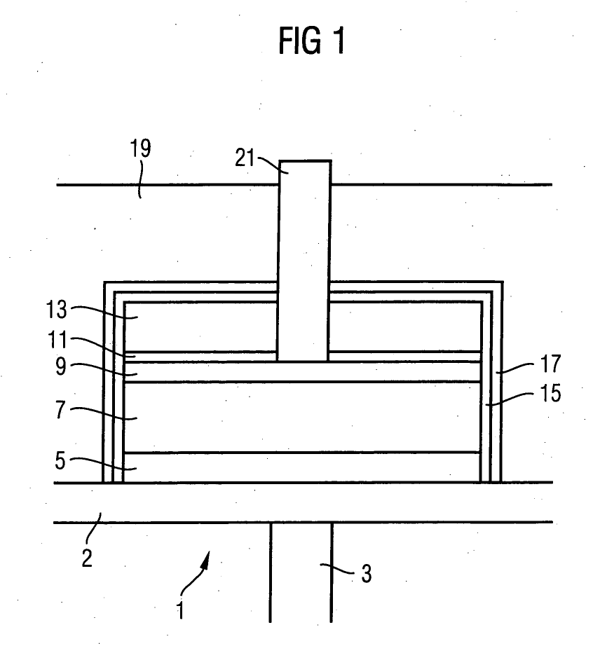

Referring to FIG. 1, an embodiment of the invention is shown which is a portion of an FeRAM device, including one or more (usually many) ferrocapacitors of the form shown in FIG. 1.

As in a conventional FeRAM device, the ferrocapacitor is formed over a substructure 1 including a layer 2 which is a conductive barrier such as lrO₂, and conductive plug 3 extending in a vertical direction for connecting the ferrocapacitor to other components of the device located on lower levels. The ferrocapacitor itself includes a bottom electrode 5 (optionally, a barrier film (not shown) is provided below the bottom electrode 5), a ferroelectric layer 7 and a top electrode 9.

Over the top electrode 9 is a sputtered cover layer 11. Over the cover layer 11 is a TEOS layer 13. These features are all known from existing FeRAM devices.

Over the TEOS layer 13, and on the sides of the layers 5, 7, 9, 11, 13 is a Al₂O₃ cover layer 15 formed by sputtering. Formed directly over the Al₂O₃ cover layer 15 is an Al₂O₃ cover layer 17 formed by ALD.

During the ALD process in which the Al₂O₃ layer 17 is formed, the Al₂O₃ layer 15 protects the ferrocapacitor, and in particular the ferroelectric layer 7, from the aggressive chemistry of the ALD process.

As in conventional methods, the capacitor is encapsulated in a TEOS layer 19. An additional conductive plug 21 may then be formed from above, extending through the TEOS layer 19, the ALD-deposited Al₂O₃ cover layer 17, the sputtered Al₂O₃ cover layer 15, the TEOS layer 13, and the cover layer 11, so that the plug 21 contacts the top electrode 9. The plug 21 is for electrically connecting the top electrode of the ferrocapacitor to other components (e.g. other ferrocapacitors) on higher levels of the structure.

During back-end processes carried out on the ferroelectric device, such as formation of IMD or passivation layers, the Al₂O₃ cover layer formed 17 by ALD protects the ferrocapacitor from the hydrogen ions generated.

Although only a single embodiment of the invention has been described, many variations are possible within the scope of the invention are possible, as will be clear to a skilled reader. For example, the sputtered layer 9 illustrated in FIG. 1 could be replaced by a first sputtered Al₂O₃ layer directly covered by an Al₂O₃ layer formed by ALD.

More generally, in known FeRAM devices there are typically more than one Al₂O₃ protective layers, and in principle any of these could be replaced by a two layer structure composed of a first Al₂O₃ layer (formed by sputtering or other physical vapour deposition process) covered by an Al₂O₃ layer formed by ALD (optionally, with an intermediate layer between them)

1. A method of forming a ferroelectric device, the method comprising:
forming a capacitor structure including, in order, a bottom electrode, a layer of ferroelectric material over the bottom electrode, and a top electrode over the ferroelectric layer;
forming a first Al₂O₃ cover layer over the capacitor structure by a physical vapour deposition process; and
forming a second Al₂O₃ cover layer over the first cover layer by an atomic layer deposition process.

2. A method according to claim 1 in which the first and second Al₂O₃ cover layers extend over the sides of the bottom electrode, ferroelectric layer and top electrode.

3. A method according to claim 1 in which the second Al₂O₃ cover layer is formed directly over the first Al₂O₃ cover layer without an intermediate layer.

4. A method according to claim 1 in which the first Al₂O₃ cover layer is spaced from the top electrode by an insulating layer.

5. A method according to claim 1 in which the physical vapour deposition process is sputtering.

6. A ferroelectric device formed by a method according to claim 1.

7. A ferroelectric device comprising:
a capacitor structure including, in order, a bottom electrode, a layer of ferroelectric material over the bottom electrode, and a top electrode over the ferroelectric layer;
a first Al₂O₃ cover layer formed over the ferrocapacitor structure by a physical vapour deposition process;
a second Al₂O₃ cover layer formed over the first Al₂O₃ cover layer by an atomic layer deposition process.

8. A device according to claim 7 in which the first and second Al₂O₃ cover layers extend over the sides of the bottom electrode, ferroelectric layer and top electrode.

9. A device according to claim 7 in which the second Al₂O₃ cover layer is formed directly over the first Al₂O₃ cover layer without an intermediate layer.

10. A device according to claim 7 in which the first Al₂O₃ cover layer is spaced from the top electrode by an insulating layer.
